(19) United States
(12) Patent Application Publication
(10) Pub. No.: US 2008/0192559 A1
(43) Pub. Date: Aug. 14, 2008

(54) Bank interleaving compound commands

(75) Inventor: Kuljit S. Bains, Clympia, WA (US)

Correspondence Address: CAVEN & AGHEVLI;c/o INTELLEVATE, LLC, P.O. BOX 52050, MINNEAPOLIS, MN, 55402, US

(73) Assignee: INTEL CORPORATION

(21) Appl. No.: 11/704,778

(22) Filed: Feb. 9, 2007

(51) Int. Cl. G11C 8/00

(52) U.S. Cl. 365/230.03

(57) ABSTRACT

Embodiments of the invention are generally directed to systems, methods, and apparatuses for bank interleaving compound commands. In some embodiments, a memory device receives a command having interleaving hooks. The memory device may access at least two pages of memory in at least two different bank groups responsive, at least in part, to receiving the command.

### TECHNICAL FIELD

Embodiments of the invention generally relate to the field of integrated circuits and, more particularly, to systems, methods, and apparatuses for bank interleaving compound commands.

### BACKGROUND

Memory systems typically include a controller coupled to one or more memory devices through a memory interconnect. In operation, the controller issues commands and provides write data to the memory devices over the memory interconnect. Similarly, the memory devices provide read data to the controller over the memory interconnect.

The term “interleaving” refers to mapping data across banks in a memory system. In some cases, the controller interleaves data to create logical pages. In conventional systems, the controller issues a sequence of individual (or single) commands to perform read and write operations on interleaved data. As the number of these commands increase, they consume an increasing large fraction of the bandwidth of the memory interconnect.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a high-level block diagram illustrating selected aspects of a computing system implemented according to an embodiment of the invention.

FIG. 2 is a block diagram illustrating selected aspects of a dynamic random access memory (DRAM) implemented according to an embodiment of the invention.

FIG. 3 is a block diagram illustrating selected aspects of a ×4/×8 memory device implemented according to an embodiment of the invention.

FIG. 4 is a timing diagram illustrating selected aspects of a command having interleaving hooks according to an embodiment of the invention.

FIG. 5 is a flow diagram illustrating selected aspects of a command having interleaving hooks, according to an embodiment of the invention.

FIG. 6 is a block diagram illustrating selected aspects of an electronic system according to an embodiment of the invention.

FIG. 7 is a bock diagram illustrating selected aspects of an electronic system according to an alternative embodiment of the invention.

### DETAILED DESCRIPTION

Embodiments of the invention are generally directed to systems, methods, and apparatuses for bank interleaving compound commands. In some embodiments, a single command is sufficient to perform an operation on two (or, possibly, more) banks that provide a logical page of memory. The term “command having interleaving hooks” is used to refer to such a command because it includes the interleaving hooks that enable it to operate on more than one bank. In some embodiments, these commands reduce the need for command bandwidth on the interconnect and enable that bandwidth to be used for other purposes (such as write data). In addition, since the command bandwidth is reduced, the memory interconnect can be operated at a lower frequency. In some embodiments, the amount of power consumed by the memory system is reduced because the memory interconnect is operated at a lower frequency.

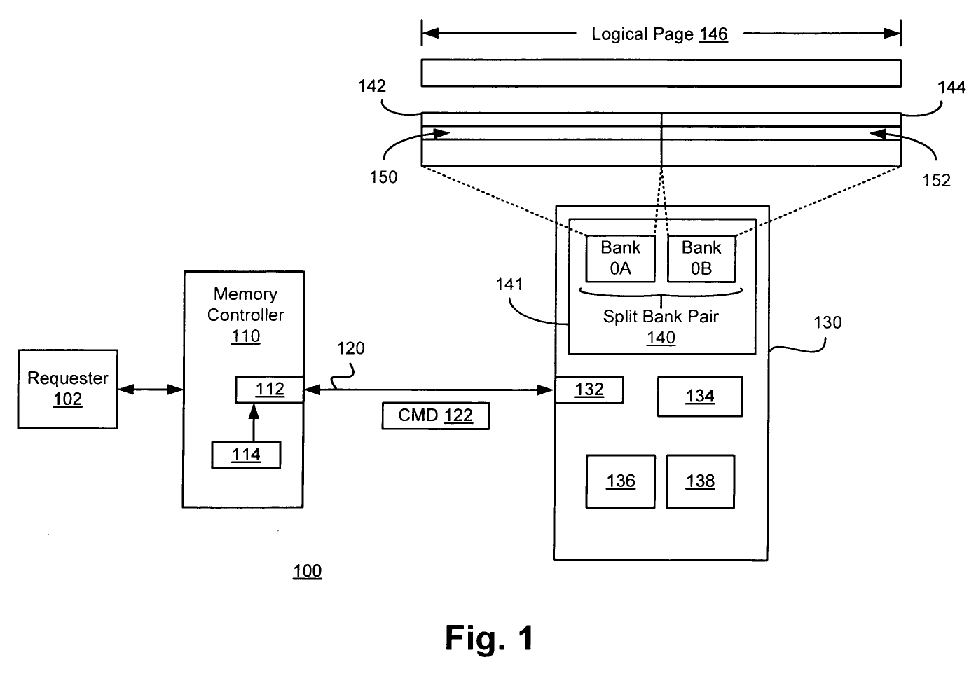

FIG. 1 is a high-level block diagram illustrating selected aspects of a computing system implemented according to an embodiment of the invention. Computing system 100 includes requester 102, memory controller (or host) 110, memory device 130, and interconnect (or memory interconnect) 120. Memory controller 110 controls, at least in part, the transfer of information between requester 102 and memory device 130. Requester 102 may be a processor (e.g., a central processing unit and/or a core), a service processor, an input/output device (e.g., a peripheral component interconnect (PCI) Express device), memory itself, or any other element of system 100 that requests access to memory. In some embodiments, memory controller 110 is on the same die as requester 102.

In the illustrated embodiment, memory controller 110 includes, inter alia, interface 112 and logic 114. Interface 112 provides an interface to interconnect 120. Interface 112 may include any number of receivers, drivers, clocking circuits, and the like suitable for communicating over interconnect 120.

As is further discussed below, in some embodiments, logic 114 issues commands having interleaving hooks (e.g., command 122) to memory device 130. The bandwidth consumed by commands on interconnect 120 can be reduced because one command is sufficient to execute an operation (e.g., read, write, etc.) on data that is interleaved on more than one bank (e.g., interleaved on banks 0A and 0B). In some embodiments, logic 114 inspects a request received from requester 102 and dynamically determines whether to issue, for example, a simple command, a compound command, or a command having interleaving hooks.

Memory device 130 may be any of a wide range of devices including a dynamic random access memory device (or, simply, a DRAM). Memory core 141 may be organized into one or more split bank pairs 140. A split bank pair refers to a pair of memory banks that can be configured as either a single bank or as two separate banks. In some embodiments, each bank of the split bank pair has its own row decoder and column decoder.

In some embodiments, each bank of the split bank pair can provide a page of memory. For example, bank 0A provides page 142 and bank 0B provides page 144. A “bank” refers to an array of memory locations provided by a memory device. Collectively, banks 142 and 144 can provide logical page 146. The term “logical page” refers to a logical combination of two or more physical banks. In some embodiments, pages 142 and 144 each provide 1 kilobytes (K bytes) of memory and logical page 146 provides a net effective page size of 2K bytes. For ease of discussion, some embodiments of the invention are described with reference to a logical page that spans two banks. It is to be appreciated, however, that a logical page may span a different number of banks (e.g., 4 banks, 8 banks, etc.) and that interleaving hooks may be applied over virtually any number of banks.

In the illustrated embodiment, memory device 130 includes interface 132, logic 134, registers 136, and posted write buffer (PWB) 138. Interface 132 provides an interface to interconnect 120. Interface 132 may include any number of receivers, drivers, clocking circuits, and the like suitable for communicating over interconnect 120.

Logic 134 receives a command having interleaving hooks (e.g., command 122) from interconnect 120. In some embodiments, logic 134 decodes the received command and issues two or more simple commands to memory core 141 to execute the received command. As is further described below, in some embodiments, logic 134 accesses (or opens) at least two pages of memory (e.g., pages 142 and 144) in at least two different banks (and/or two different bank groups) in response to receiving the command.

Register 136 provides values (e.g., timing values such as tRRD, tRCD, tCL, etc.) to enable logic 134 to issue commands to memory core 141 in a deterministic fashion. In some embodiments, register 136 is part of a mode register set (MRS). Posted write buffer (PWB) 134 is a buffer into which data is loaded prior to be written to memory core 141. It is to be appreciated that PWB 134 is optional and that some embodiments may not include PWB 134.

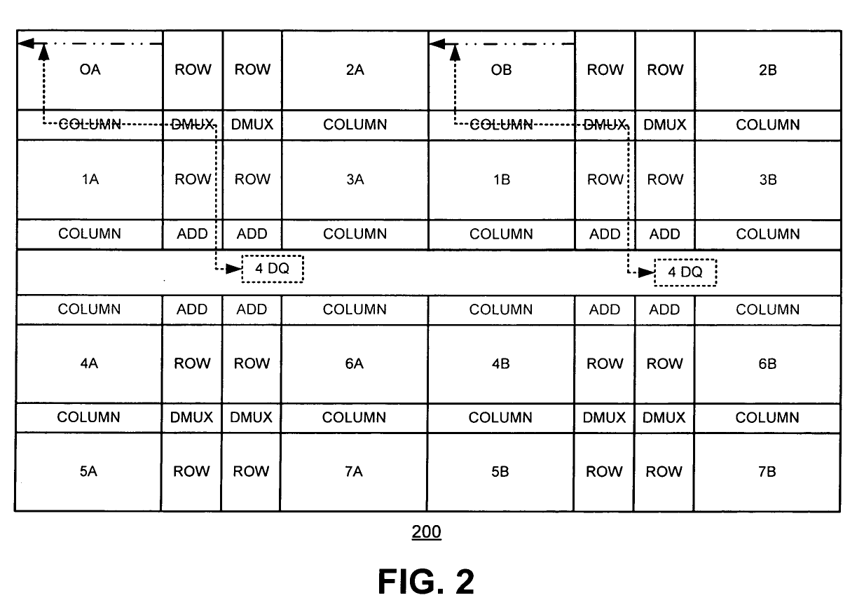

FIG. 2 is a block diagram illustrating selected aspects of a dynamic random access memory (DRAM) implemented according to an embodiment of the invention. DRAM 200 includes 16 memory banks (0A through 7B) or 8 split bank pairs (e.g., split bank pair 0A, 0B). In some embodiments, DRAM 200 can be configured as either a ×4 or a ×8 DRAM. In ×4 mode, DRAM 200 provides 16 banks (0A through 7B) and each bank provides 64 bits of data to 4 data (DQ) pins. In ×8 mode, DRAM 200 provides 8 split bank pairs to provide 128 bits of data to 8 DQ pins.

In some embodiments, DRAM 200 can be configured to operate in either an error check mode (e.g., an ECC mode) or a non-error check mode. When operating in an error check mode, DRAM 200 leverages its split bank architecture by storing data in one member of the split bank (e.g., bank 0A) and corresponding error check bits (e.g., ECC bits) in the other member of the split bank (e.g., bank 0B). In some embodiments, DRAM 200 is configured as a ×8 DRAM when it is operating in the error check mode.

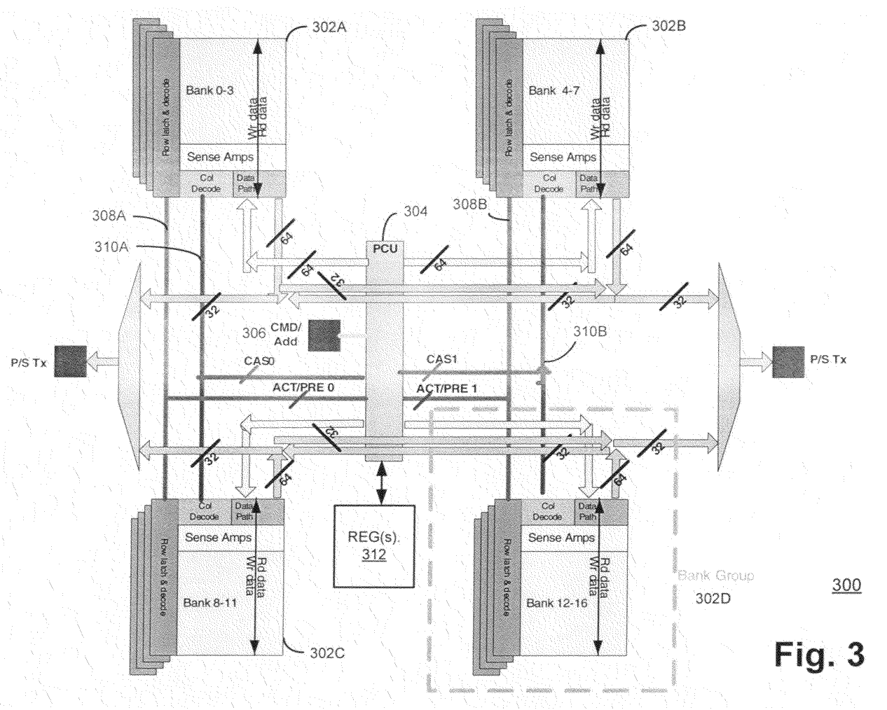

FIG. 3 is a block diagram illustrating selected aspects of a ×4/×8 memory device implemented according to an embodiment of the invention. In ×4 mode, memory device 300 has four bank groups (302) with each bank group having four banks. In some embodiments, each bank has a page size of 1K. In ×4 mode, one bank is accessed for each access and all 64 bits of data are fetched from one bank. For ease of discussion, embodiments of the invention are described with respect to a ×4 /×8 device but it is to be appreciated that other embodiments of the invention may include devices of different widths such as ×2, ×8, ×16, ×32, and the like. Alternative embodiments of the invention may have more elements, fewer elements, different elements, and/or may be structured differently.

Memory device 300 includes port control unit (PCU) 304. PCU 304 receives commands (CMD's) and addresses from a controller (e.g., controller 110, shown in FIG. 3) and, in response, issues commands to bank groups 302 (based on certain timing parameters that may be preprogrammed into PCU 304). For example, in the illustrated embodiment, PCU 304 receives CMD's and addresses at block 306. PCU 304 issues access and precharge CMD's to the various row decoders of the banks over interconnect 308. Similarly, PCU 304 issues CAS commands to the banks over interconnect 310. The term “CAS commands” broadly refers to column commands such as read commands and write commands.

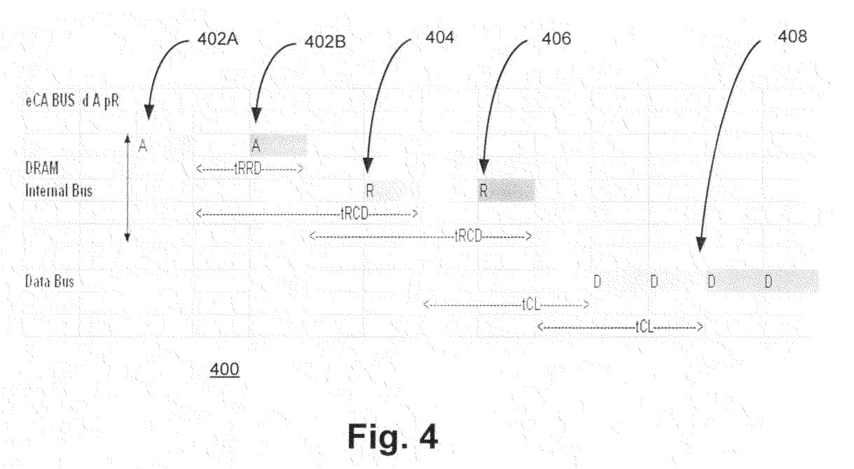

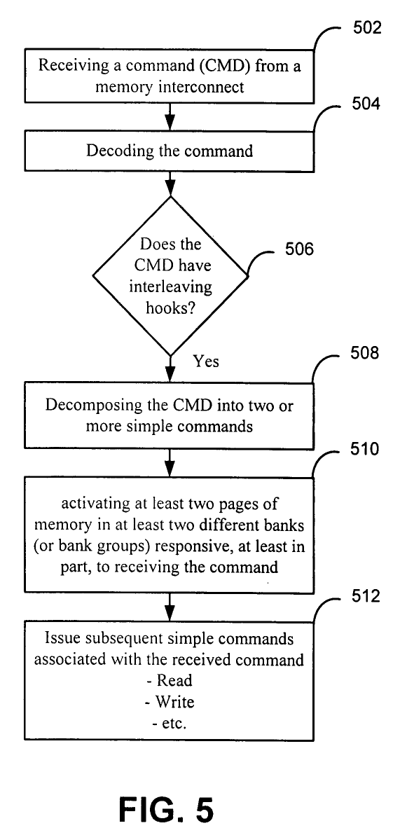

In some embodiments, PCU 304 receives a command having interleaving hooks and, based on the command, operates on (e.g., issues a command to) more than bank and/or more than one bank group. For example, PCU 304 may receive the command having interleaving hooks at block 306. In some embodiments, PCU 304 decodes the command and decomposes it into two or more simple commands. The simple commands are issued to the banks (and/or bank groups) in accordance with timing restrictions that ensure deterministic operation. In some embodiments, PCU 304 references registers 312 to look-up various timing values such as tCL, tRRD, tRCD, and the like. Selected aspects of PCU 304 are further discussed below with reference to FIGS. 4-5.

FIG. 4 is a timing diagram illustrating selected aspects of a command having interleaving hooks according to an embodiment of the invention. In particular, timing diagram 400 illustrates the execution of a dual activate and posted read command (d-A-pR). In response to receiving a d-A-pR command, a PCU (e.g. PCU 300, shown in FIG. 3) activates two pages of memory in two different bank groups (402). The two pages may be activated at the same row address in two split banks in different bank groups. The activation of these pages can be simultaneous or staggered by, for example, tRRD (depending, perhaps, on a power budget). If the activation is staggered, then the first page that is activated may be indicated by the bank (and row) address in the frame packet.

After a delay of tRCD, the PCU issues a read command to the first bank that was activated as indicated by the bank address (and the column address) in the frame (404). The PCU issues the second read command to the second bank that was activated after a delay (406). In some embodiments, the delay may be determined by a value such as tCCD_S (or two frames) which may be stored in a register (e.g., register 312, shown in FIG. 3). The second read command may also satisfy the tRCD delay from the second activate command (402B). In the illustrated embodiment, the data is driven on the DQ bus (408) after a delay of, for example, tCL (CAS latency). Thus, two frames of data may be delivered per read request.

The command bandwidth savings provided by an embodiment of the invention can be illustrated by comparing a command having interleaving hooks with other kinds of commands. For example, if the above described operation were to be performed using single commands (over the memory interconnect) then the controller would have to issue four commands: activate 1, activate 2, read 1, and read 2. If the above described operation were to be performed using a compound command then the controller would have to issue two commands: activate-posted-read 1 and activate-posted-read 2. If, however, the operation is performed using a command having interleaving hooks, then the controller issues only one command: dual-activate-posted-read (d-A pR).

While the operation of the invention is illustrated using the d-A pR command, it is to be appreciated that interleaving hooks may be used in a wide variety of cases. Table 1 illustrates a selection of commands having interleaving hooks, according to some embodiments of the invention. In alternative embodiments, more commands, fewer commands, and/or different commands may have interleaving hooks. For example, in some embodiments, commands associated with auto-precharge may have interleaving hooks.

TABLE 1

| Command | Brief Description |
|---|---|
| d-A pR and d-A pW | Dual-activate-posted-read and dual- |
| | activate-posted-write |
| d-P | Dual precharge |
| d-pR (d-R is a subset of this | Dual posted read |
| command with a posting = 0) | |
| d-P-A pR and d-P-A pW | Dual-precharge-activate-posted-read and |
| | dual-precharge-activate-posted-write |

Table 2 summarizes the percentage of command bandwidth savings that may be theoretically available according to some embodiments of the invention. In alternative embodiments, the percentage of command bandwidth savings may be different.

TABLE 2
RD Case (open page policy)

| | | # cmds | # cmds using | % savings in |
|---|---|---|---|---|
| | | using | bank | cmd |
| | # cmds using | compound | interleaving | bandwidth vs. |
| | simple cmds | cmds | hooks | compound |
| # Reads/ | | | | |
| Writes in | | | | |
| sequence to a | | | | |
| logical page | | | | |
| (A + R or W) | | | | |
| 1 (two CL's) | 4 | 2 | 1 | 50% |
| 2 (three CL's) | 5 | 3 | 2 | 33% |
| 3 (four CL's) | 6 | 4 | 2 | 50% |
| Precharging | | | | |
| logical | | | | |
| pages (P) | | | | |
| 1 page | 2 | 2 | 1 | 50% |
| 2 pages | 4 | 4 | 2 | 50% |
| # Reads in | | | | |
| sequence to a | | | | |
| logical | | | | |
| page (R) | | | | |
| 1 (two CL's) | 2 | 2 | 1 | 50% |
| 2 (three CL's) | 3 | 3 | 2 | 33% |
| 3 (four CL's) | 4 | 4 | 2 | 50% |
| P-A-Rd | | | | |
| sequence | | | | |
| 1 (two CL's) | 6 | 2 | 1 | 50% |

FIG. 5 is a flow diagram illustrating selected aspects of a command having interleaving hooks, according to an embodiment of the invention. Referring to reference number 502, a PCU (e.g., PCU 304, shown in FIG. 3 or other logic) receives a command from a memory interconnect (e.g., memory interconnect 120, shown in FIG. 1). The PCU decodes the command at 504. If the command has interleaving hooks (or is another type of compound command), the PCU decomposes the command into two or more simple commands (506 and 508). The term “simple command” refers to a command that performs a relatively simple activity such as an activate command, a read command, a write command, a precharge command, and the like.

Referring to process block 510, the PCU accesses at least two pages of memory in at least two different bank groups responsive, at least in part, to receiving the command having interleaving hooks. The PCU issues subsequent simple commands to the memory array, as appropriate, to perform the operation specified by the command having interleaving hooks. For example, the PCU may issue a number of read commands (to different banks and/or to different bank groups) to read data from the memory array. Alternatively, the PCU may issue a number of write commands to write data to the memory array. In addition, the PCU may issue a wide variety of other simple commands in response to receiving the command having interleaving hooks.

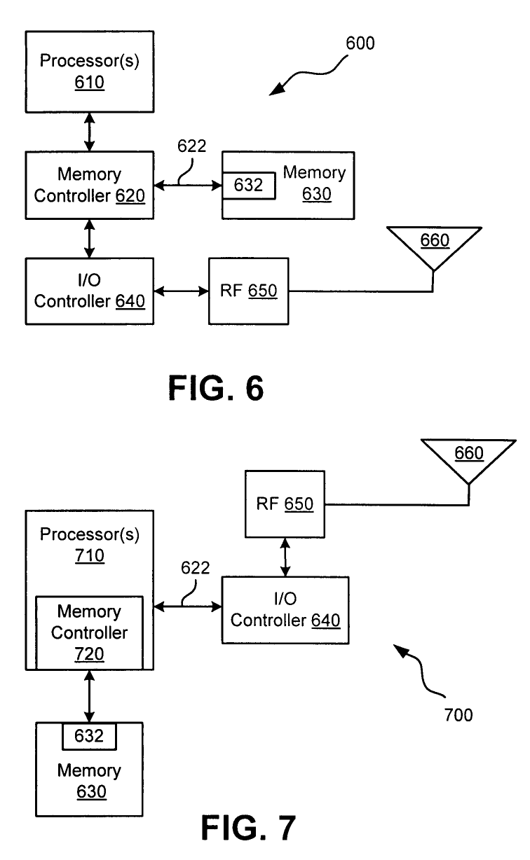

FIG. 6 is a block diagram illustrating selected aspects of an electronic system according to an embodiment of the invention. Electronic system 600 includes processor 610, memory controller 620, memory 630, input/output (I/O) controller 640, radio frequency (RF) circuits 650, and antenna 660. In operation, system 600 sends and receives signals using antenna 660, and these signals are processed by the various elements shown in FIG. 6. Antenna 660 may be a directional antenna or an omni-directional antenna. As used herein, the term omni-directional antenna refers to any antenna having a substantially uniform pattern in at least one plane. For example, in some embodiments, antenna 660 may be an omni-directional antenna such as a dipole antenna or a quarter wave antenna. Also, for example, in some embodiments, antenna 660 may be a directional antenna such as a parabolic dish antenna, a patch antenna, or a Yagi antenna. In some embodiments, antenna 660 may include multiple physical antennas.

Radio frequency circuit 650 communicates with antenna 660 and I/O controller 640. In some embodiments, RF circuit 650 includes a physical interface (PHY) corresponding to a communication protocol. For example, RF circuit 650 may include modulators, demodulators, mixers, frequency synthesizers, low noise amplifiers, power amplifiers, and the like. In some embodiments, RF circuit 650 may include a heterodyne receiver, and in other embodiments, RF circuit 650 may include a direct conversion receiver. For example, in embodiments with multiple antennas 660, each antenna may be coupled to a corresponding receiver. In operation, RF circuit 650 receives communications signals from antenna 660 and provides analog or digital signals to I/O controller 640. Further, I/O controller 640 may provide signals to RF circuit 650, which operates on the signals and then transmits them to antenna 660.

Processor(s) 610 may be any type of processing device. For example, processor 610 may be a microprocessor, a microcontroller, or the like. Further, processor 610 may include any number of processing cores or may include any number of separate processors.

Memory controller 620 provides a communication path between processor 610 and other elements shown in FIG. 6. In some embodiments, memory controller 620 is part of a hub device that provides other functions as well. As shown in FIG. 6, memory controller 620 is coupled to processor(s) 610, I/O controller 640, and memory 630. In some embodiments, memory controller 620 (and/or memory controller 720, shown in FIG. 7) issues commands having interleaving hooks to memory 530.

Memory 630 may include multiple memory devices. These memory devices may be based on any type of memory technology. For example, memory 630 may be random access memory (RAM), dynamic random access memory (DRAM), static random access memory (SRAM), nonvolatile memory such as FLASH memory, or any other type of memory. In some embodiments, memory 630 includes logic 632 (e.g., a PCU) which is capable of operating on more than one bank (and/or more than one bank group) in response to receiving the command having interleaving hooks.

Memory 630 may represent a single memory device or a number of memory devices on one or more modules. Memory controller 620 provides data through interconnect 622 to memory 630 and receives data from memory 630 in response to read requests. Commands and/or addresses may be provided to memory 630 through interconnect 622 or through a different interconnect (not shown). Memory controller 620 may receive data to be stored in memory 630 from processor 610 or from another source. Memory controller 620 may provide the data it receives from memory 630 to processor 610 or to another destination. Interconnect 622 may be a bidirectional interconnect or a unidirectional interconnect. Interconnect 622 may include a number of parallel conductors. The signals may be differential or single ended. In some embodiments, interconnect 622 operates using a forwarded, multiphase clock scheme.

Memory controller 620 is also coupled to I/O controller 640 and provides a communications path between processor(s) 610 and I/O controller 640. I/O controller 640 includes circuitry for communicating with I/O circuits such as serial ports, parallel ports, universal serial bus (USB) ports and the like. As shown in FIG. 6, I/O controller 640 provides a communication path to RF circuits 650.

FIG. 7 is a bock diagram illustrating selected aspects of an electronic system according to an alternative embodiment of the invention. Electronic system 700 includes memory 730, I/O controller 740, RF circuits 750, and antenna 760, all of which are described above with reference to FIG. 7. Electronic system 700 also includes processor(s) 710 and memory controller 720. As shown in FIG. 7, memory controller 720 may be on the same die as processor(s) 710. Processor(s) 710 may be any type of processor as described above with reference to processor 710 (FIG. 5). Example systems represented by FIGS. 6 and 7 include desktop computers, laptop computers, servers, cellular phones, personal digital assistants, digital home systems, and the like.

Elements of embodiments of the present invention may also be provided as a machine-readable medium for storing the machine-executable instructions. The machine-readable medium may include, but is not limited to, flash memory, optical disks, compact disks-read only memory (CD-ROM), digital versatile/video disks (DVD) ROM, random access memory (RAM), erasable programmable read-only memory (EPROM), electrically erasable programmable read-only memory (EEPROM), magnetic or optical cards, propagation media or other type of machine-readable media suitable for storing electronic instructions. For example, embodiments of the invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Further more, the particular features, structures or characteristics may be combined as suitable in one or more embodiments of the invention.

Similarly, it should be appreciated that in the foregoing description of embodiments of the invention, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

What is claimed is:

1. A memory device comprising:
an interface to be coupled with a memory interconnect; and
logic to receive a command having interleaving hooks from the memory interconnect and to access at least two pages of memory in at least two different bank groups responsive, at least in part, to receiving the command.

2. The memory device of claim 1, wherein the logic to access at least two pages of memory in at least two different bank groups responsive, at least in part, to receiving the command comprises:
logic to simultaneously access at least two pages of memory in at least two different bank groups responsive, at least in part, to receiving the command.

3. The memory device of claim 1, wherein the logic to access at least two pages of memory in at least two different bank groups responsive, at least in part, to receiving the command comprises:
logic to access a first page of memory in a first bank group; and
logic to access a second page of memory in a second bank group, subsequent to activating the first page of memory.

4. The memory device of claim 1, wherein the logic to receive the command having interleaving hooks from the memory interconnect comprises:
logic to decode the command having interleaving hooks; and
logic to decompose the command having interleaving hooks into two or more single commands.

5. The memory device of claim 4, wherein the logic to receive the command having interleaving hooks from the memory interconnect further comprises:
logic to issue the two or more single commands to a memory core.

6. The memory device of claim 5, wherein the logic to issue the two or more single commands to a memory core comprises:
logic to deterministically issue the two or more single commands to a memory core based, at least in part, on one or more values stored in a register.

7. The memory device of claim 1, wherein the command having interleaving hooks comprises:
a column address strobe (CAS) command having interleaving hooks.

8. The memory device of claim 7, wherein the CAS command having interleaving hooks comprises one of:
a read command having interleaving hooks; and
a write command having interleaving hooks.

9. The memory device of claim 1, wherein the memory device is a dynamic random access memory device.

10. A method comprising:
receiving a CAS command having interleaving hooks from a memory interconnect; and
activating at least two pages of memory in at least two different bank groups responsive, at least in part, to receiving the CAS command.

11. The method of claim 10, wherein activating at least two pages of memory in at least two different bank groups responsive, at least in part, to receiving the CAS command comprises:
simultaneously activating at least two pages of memory in at least two different bank groups responsive, at least in part, to receiving the CAS command.

12. The method of claim 10, wherein activating at least two pages of memory in at least two different bank groups responsive, at least in part, to receiving the CAS command comprises:
activating a first page of memory in a first bank group; and
activating a second page of memory in a second bank group, subsequent to activating the first page of memory.

13. The method of claim 10, wherein the CAS command is a read command.

14. The method of claim 11, further comprising:
driving data on the memory interconnect responsive, at least in part, to the read command.

15. A system comprising:
a controller coupled with a memory interconnect; and
a memory device coupled with the memory interconnect, wherein the memory device includes logic to receive a CAS command having interleaving hooks from the memory interconnect and to access at least two pages of memory in at least two different bank groups responsive, at least in part, to receiving the CAS command.

16. The system of claim 15, wherein the logic to access at least two pages of memory in at least two different bank groups responsive, at least in part, to receiving the CAS command comprises:
logic to simultaneously access at least two pages of memory in at least two different bank groups responsive, at least in part, to receiving the CAS command.

17. The system of claim 15, wherein the logic to receive the CAS command having interleaving hooks from the memory interconnect comprises:
logic to decode the CAS command having interleaving hooks; and
logic to decompose the CAS command having interleaving hooks into two or more single commands.

18. The system of claim 17, wherein the logic to receive the CAS command having interleaving hooks from the memory interconnect further comprises:
logic to issue the two or more single commands to a memory core.

19. The system of claim 15, wherein the controller includes logic to issue the CAS command having interleaving hooks.

20. The system of claim 19, wherein the logic to issue a CAS command having interleaving hooks comprises:
logic to dynamically determine whether to issue a CAS command having interleaving hooks.
